(19) United States
(12) Patent Application Publication
(10) Pub. No.: US 2025/0123348 A1
(43) Pub. Date: Apr. 17, 2025

(54) STATISTICAL VISUALIZATIONS AND ANOMALY DETECTION FOR VEHICLE CALIBRATION SETS

(71) Applicant: GM GLOBAL TECHNOLOGY OPERATIONS LLC, Detroit, MI (US)

(72) Inventors: Kaushik SHANBOUG VIDURA PRASAD, Canton, MI (US); Horacio Beckert Polli, Canoinhas (BR)

(21) Appl. No.: 18/485,840

(22) Filed: Oct. 12, 2023

(51) Int. Cl. G01R 35/00; G06F 17/18

(52) U.S. Cl. CPC G01R 35/005; G06F 17/18

(57) ABSTRACT

A method for detecting anomalies in vehicle calibrations sets includes receiving a plurality of vehicle calibration sets, each vehicle calibration set including corresponding vehicle parameters, calculating, for each vehicle parameter of each vehicle calibration set, an anomaly score, detecting an anomaly associated with at least one vehicle parameter of a vehicle calibration set of the plurality of vehicle calibration sets based on the anomaly score for the vehicle parameter and a defined threshold, in response to detecting the anomaly, modifying the vehicle parameter of the vehicle calibration set, and transmitting the vehicle calibration set including the modified vehicle parameter to a vehicle control module associated with a vehicle for controlling at least one component of the vehicle. Other example methods and systems for detecting anomalies in vehicle calibrations sets are also disclosed.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to visualizations and anomaly detection for vehicle calibration sets.

Vehicles depend heavily on intricate calibrations that are quintessential to defining and optimizing vehicle performance metrics, such as vibrations, range, battery efficiency, miles per gallon, emissions, etc. A set of calibrations (e.g., parameter values) for a particular vehicle is typically provided to that vehicle during production (e.g., flashing at the manufacturing plant) or in a post-production scenario (e.g., via Over-The-Air (OTA) updates or dealership flashing). In some cases, a data management system may be employed during the calibration process to check calibration values. In other examples, a manual process may be necessary in which a one-by-one comparison of each calibration parameter is evaluated.

### SUMMARY

A method for detecting anomalies in vehicle calibrations sets includes receiving a plurality of vehicle calibration sets, each vehicle calibration set including corresponding vehicle parameters, calculating, for each vehicle parameter of each vehicle calibration set, an anomaly score, detecting an anomaly associated with at least one vehicle parameter of a vehicle calibration set of the plurality of vehicle calibration sets based on the anomaly score for the vehicle parameter and a defined threshold, in response to detecting the anomaly, modifying the vehicle parameter of the vehicle calibration set, and transmitting the vehicle calibration set including the modified vehicle parameter to a vehicle control module associated with a vehicle for controlling at least one component of the vehicle.

In other features, the plurality of vehicle calibration sets includes a master vehicle calibration set and one or more child vehicle calibration sets.

In other features, calculating the anomaly score includes calculating a gradient for each corresponding vehicle parameter of the plurality of vehicle calibration sets, calculating one or more numerical relationships for each corresponding vehicle parameter of each child vehicle calibration set against a corresponding vehicle parameter of the master vehicle calibration set, and calculating the anomaly score based on a cost function, a weighted value of the gradient, and weighted values of the one or more numerical relationships.

In other features, the one or more numerical relationships include a Euclidean distance and a linear regression.

In other features, calculating the anomaly score includes calculating a gradient for each corresponding vehicle parameter of the plurality of vehicle calibration sets, and calculating one or more numerical relationships for each corresponding vehicle parameter of each vehicle calibration set against a corresponding vehicle parameter of all other vehicle calibration sets.

In other features, calculating the anomaly score includes calculating a provisional anomaly score for each corresponding vehicle parameter of the plurality of vehicle calibration sets based on a cost function, a weighted value of the gradient, and weighted values of the one or more numerical relationships, setting the vehicle calibration set having the corresponding vehicle parameter with a lowest provisional anomaly score as a reference vehicle calibration set, and calculating the anomaly score by adjusting the provisional anomaly score for each corresponding vehicle parameter based on the reference vehicle calibration set.

In other features, the one or more numerical relationships includes a Euclidean distance and a linear regression.

In other features, calculating the anomaly score includes calculating a distance for each corresponding vehicle parameter of each child vehicle calibration set against a corresponding vehicle parameter of the master vehicle calibration set, and calculating the anomaly score based on the distance.

In other features, calculating the anomaly score includes calculating a normalized value of the distance and setting the anomaly score to equal the normalized value.

In other features, calculating the anomaly score includes calculating a mean for each corresponding vehicle parameter of the plurality of vehicle calibration sets, calculating a distance for each corresponding vehicle parameter of each vehicle calibration set against the calculated mean for that vehicle parameter, and calculating the anomaly score based on the distance.

In other features, calculating the anomaly score includes calculating a normalized value of the distance and setting the anomaly score to equal the normalized value.

In other features, the method further includes detecting whether the plurality of vehicle calibration sets are in a scalar format.

In other features, calculating the anomaly score includes, in response to the plurality of vehicle calibration sets being in the scalar format, calculating a distance for each corresponding vehicle parameter of each set of vehicle calibrations against a reference value and calculating the anomaly score based on the distance.

In other features, the method further includes detecting whether the plurality of vehicle calibration sets are in a vector format or a map format.

In other features, calculating the anomaly score specific to each set of vehicle calibrations includes calculating the anomaly score based on a cost function in response to the plurality of vehicle calibration sets being in the vector format or the map format.

In other features, the method further includes transmitting a visualization including the anomaly score associated with the detected anomaly to a display module.

In other features, the visualization includes at least one graph charting the anomaly score.

In other features, the method further include receiving user input in response to the transmitted visualization, wherein modifying the vehicle parameter of the vehicle calibration set includes modifying the vehicle parameter of the vehicle calibration set in response to the received user input.

In other features, the method further includes calculating one or more statistical relationships of corresponding vehicle parameters of the plurality of vehicle calibration sets, and transmitting a visualization including at least one table charting the one or more statistical relationships to a display module.

In other features, the method further includes receiving a defined autocorrect threshold.

In other features, modifying the vehicle parameter of the vehicle calibration includes autocorrecting the vehicle parameter of the vehicle calibration to a reference calibration in response to the detected anomaly being greater than the defined autocorrect threshold.

In other features, transmitting the vehicle calibration set including the modified vehicle parameter to the vehicle control module includes transmitting the vehicle calibration set to the vehicle control module associated with the vehicle via an over-the-air (OTA) update.

A method for detecting anomalies in vehicle calibrations sets includes receiving a plurality of vehicle calibration sets, each vehicle calibration set including corresponding vehicle parameters divided into two or more sections, calculating, for each section of each vehicle calibration set, an anomaly score, detecting an anomaly associated with at least one section of a vehicle calibration set of the plurality of vehicle calibration sets based on the anomaly score for the section and a defined threshold, in response to detecting the anomaly, modifying a vehicle parameter in the section of the vehicle calibration set, and transmitting the vehicle calibration set including the modified vehicle parameter to a vehicle control module associated with a vehicle for controlling at least one component of the vehicle.

A system for detecting anomalies in vehicle calibrations sets includes a vehicle control module associated with a vehicle for controlling at least one component of the vehicle, and a control module in communication with the vehicle control module. The control module is configured to receive a plurality of vehicle calibration sets, each vehicle calibration set including corresponding vehicle parameters, calculate, for each vehicle parameter of each vehicle calibration set, an anomaly score, detect an anomaly associated with at least one vehicle parameter of a vehicle calibration set of the plurality of vehicle calibration sets based on the anomaly score for the vehicle parameter and a defined threshold, in response to detecting the anomaly, modify the vehicle parameter of the vehicle calibration set, and transmit the vehicle calibration set including the modified vehicle parameter to a vehicle control module associated with a vehicle for controlling at least one component of the vehicle.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example system for detecting anomalies in vehicle calibrations sets and generating statistical visualizations of the vehicle calibrations sets, according to the present disclosure;

FIGS. 2-5 are graphs depicting anomaly scores for corresponding vehicle parameters of different calibration sets when a master calibration set is employed, according to the present disclosure;

FIGS. 6-9 are graphs depicting anomaly scores for corresponding vehicle parameters of different calibration sets when a master calibration set is not employed, according to the present disclosure;

FIGS. 10-13 are graphs depicting anomaly scores for corresponding vehicle parameters of four separate sections of two calibration sets, according to the present disclosure;

FIG. 14 is a graph depicting anomaly scores for vehicle parameters of four collective sections of one of the two calibration sets of FIGS. 10-13, according to the present disclosure;

FIG. 15 is a graph depicting anomaly scores for vehicle parameters of four collective sections of another one of the two calibration sets of FIGS. 10-13, according to the present disclosure;

FIG. 16 is a graph depicting anomaly scores for vehicle parameters of four collective sections of the two calibration sets of FIGS. 10-13, according to the present disclosure;

FIGS. 17-22 are flowcharts of example control processes for detecting anomalies in vehicle calibrations sets, generating statistical visualizations of the vehicle calibrations sets, and/or modifying vehicle calibrations, according to the present disclosure;

FIG. 23 is a functional block diagram of an example system for updating one or more calibrations and transmitting of the new calibrations to a manufacturing facility and/or a post-production vehicle, according to the present disclosure;

FIG. 24 is a vehicle including portions of the system of FIG. 1, according to the present disclosure; and

FIG. 25 is a diagram showing interactions between nine vehicle calibration sets, according to the present disclosure.

In the drawings, reference numbers may be reused to identify similar and/or identical elements.

### DETAILED DESCRIPTION

Calibrations are used vehicles to define and optimize vehicle performance metrics, such as vibrations, range, battery efficiency, miles per gallon, emissions, etc. The number of calibrations per vehicle is significant. For example, in one vehicle, the electric propulsion system alone may utilize over 18,000 calibratable parameters that are crucial for optimal vehicle performance. Other controllable vehicle components may utilize a similar number parameters. As such, the total number of parameters for the vehicle may extend into the hundreds of thousands. Such calibrations (e.g., parameters values) are provided (e.g., flashed into a memory circuit of or associated with a vehicle control module) to vehicles during production or in post-production scenarios. In some cases, flawed calibrations may be inadvertently released for vehicles which may require recalls. For example, flawed calibrations pose significant risks to users (e.g., drivers, passengers, bystanders, etc.) and vehicles by jeopardizing user safety and vehicle performance. Additionally, flawed calibrations may impose significant and burdensome economic implications should recalls become necessary post-production. While recalls are undesirable as they have huge financial and safety implications, recalls happen more frequently than desired and many times calibration outliers/anomalies are the root cause.

Some data management systems are available for checking vehicle calibrations. However, such systems are unable to handle large datasets and/or are unreliable when handling large datasets of calibrations across multiple vehicle programs (e.g., especially comparing curves and maps with multiple data sets which are very cumbersome). As a result, companies frequently resort to a manual approach, a process involving the one-by-one comparison of each calibration parameter. This manual approach is both time consuming and prone to human error. As such, like the existing data management systems, the manual approach is not feasible and unreliable.

The systems and methods according to the present disclosure provide technical solutions for implementing anomaly detection algorithms capable of examining scalars and complex calibration maps (e.g., 1D, 2D, 3D, etc. calibration maps) to accurately identify anomalies in parameter values associated with various vehicle calibration sets having thousands (and some cases hundreds of thousands) of parameters, and then providing unique visualizations of the vehicle calibration sets. With such systems and methods, an array of intricate calibration anomalies may be distilled into a singular, easily interpretable numeric representation, thereby empowering calibration engineers with a potent tool to pinpoint and correct discrepancies before integration into the vehicle production line as further explained herein. In addition, the systems and methods remain functional post-production, offering a safety net through the ability to transmit necessary fixes or solutions to the customer's vehicle via Over-The-Air (OTA) updates, thereby circumventing potential recalls while enhancing vehicle safety and quality in real-time.

Numerous other benefits result from the detection of anomalies in parameter values. For example, by enabling rapid responses to calibration errors, the technical solutions significantly bolster vehicular safety, averting potential hazards proactively. Additionally, the technical solutions facilitate early detection and correction of calibration errors, averting the substantial costs associated with vehicle recalls. Further, with the production of a vast range of vehicles, each encompassing thousands (and some cases hundreds of thousands) of unique calibrations and numerous variants, the technical solutions enable scalability, harmoniously integrating into expansive production ecosystems. Moreover, the technical solutions herein help catch safety critical calibration errors even before the errors reach customers, save millions of dollars spent otherwise on fixing the recalls, and improve performance by updating the feature calibrations.

In addition, the technical solutions herein significantly reduce time and cost requirements associated with vehicle calibration processes. For example, the technical solutions may provide a reduction in engineer time, on average across multiple different vehicle programs, of at least sixteen weeks per engineer per year as compared to conventional systems not employing the technical solutions herein. As a result of such significant engineer time savings, engineers may focus attention on other requirements, costs may be significantly reduced, etc.

Referring now to FIG. 1, a block diagram of an example system 100 is presented for detecting anomalies in vehicle calibrations sets and generating statistical visualizations of the vehicle calibrations sets. The system 100 of FIG. 1 may be applicable for any suitable vehicle, such as an electric vehicle (e.g., a pure electric vehicle, a plug-in hybrid electric vehicle, etc.), an internal combustion engine vehicle, etc. Additionally, the system 100 may be applicable for autonomous vehicles, such as semi-autonomous vehicles and fully autonomous vehicles. For example, and as further explained, vehicle calibrations sets analyzed and in some cases modified by the system 100 may be provided to one or more vehicle control modules in any suitable vehicle.

As shown in FIG. 1, the system 100 generally includes a control module 102, a vehicle calibration database 104, a display module 106, and at least one vehicle control module 108. In such examples, the control module 102 may be in communication with each of the other components as shown in FIG. 1. Although FIG. 1 illustrates the system 100 as including specific modules, it should be appreciated that one or more other modules may be employed if desired. Additionally, while the system 100 is shown as including multiple separate modules, any combination of the modules and/or the functionality thereof may be integrated into one or more modules.

In the example of FIG. 1, the vehicle control module 108 may be any suitable control associated with a vehicle for controlling at least one component of the vehicle. In such examples, the vehicle control module 108 may be any control module in the vehicle that receives calibratable parameters. For example, the vehicle control module 108 may be an engine control module ECM for controlling a motor/an engine (e.g., en electric motor, an internal combustion engine, etc.), a battery control module for controlling battery operations (e.g., output current, charging current, etc.), an inverter control module for controlling outputs to the battery, etc.

While the system 100 of FIG. 1 is shown as including only one vehicle control module 108, it should be appreciated that the system 100 may include multiple vehicle control modules. In such examples, each vehicle control module may receive dedicated calibratable parameters specific to that vehicle control module.

The display module 106 may be any suitable device having a display. For example, the display module 106 may be a user device, such as a laptop, a phone, a monitor, a desktop computing device, etc. In such examples, the display module 106 displays one or more visualizations relating to the analysis of vehicle calibrations sets, as further explained herein.

The vehicle calibration database 104 of FIG. 1 stores various vehicle calibration sets each of which may be receivable by the control module 102. For example, each set of vehicle calibrations may include multiple parameters (e.g., thousands, etc.) for controlling different aspects of the vehicle. Each parameter may have an associated value. While the system 100 of FIG. 1 is shown as including only one vehicle calibration database 104, it should be appreciated that the system 100 may include multiple databases if desired.

In various embodiments, the vehicle calibration sets and/or the parameters therein may be in different formats. For example, in every calibration set, a combination of scalar, curve and map formats may exist. For instance, vehicle calibrations in a calibration set may have a scalar type format in which parameters are associated with a single value, a vector (or curve) type format in which parameters are associated with multiple values in one line (e.g., values alone an axis), and/or a map type format in which parameters are associated with multiple values across multiple lines (e.g., a grid of values associated with two axes). In some examples, the scalar format, the vector format, and the map format may be referred to as a 1D (one-dimensional) format, a 2D (two-dimensional) format, and a 3D (three-dimensional) format, respectively.

In some examples, the stored vehicle calibration sets may include master and child vehicle calibration sets. For example, a master vehicle calibration set may include vehicle calibrations associated with a vehicle program (e.g., a particular type of manufactured vehicle). Relatedly, child vehicle calibration sets may include vehicle calibrations associated with different vehicle setups for the vehicle program or associated programs that share components with the vehicle program (e.g., different example setups for the particular type of manufactured vehicle). In various embodiments, each vehicle program may have over fifty vehicle calibration sets with each vehicle calibration set having thousands of parameters.

In other examples, the vehicle calibration sets may not include a master vehicle calibration set. In such examples, child vehicle calibration sets of the same vehicle program (e.g., a particular type of manufactured vehicle) or different vehicle programs (e.g., two or more types of manufactured vehicles) may be analyzed as further explained below.

With continued reference to FIG. 1, the control module 102 receives vehicle calibration sets from the vehicle calibration database 104 and/or another suitable source. For example, the control module 102 may import any number of vehicle calibration sets, such as all of the vehicle calibration sets for a vehicle program, all or selected ones of the vehicle calibration sets for multiple vehicle programs, etc. Additionally, the control module 102 may be capable of importing and supporting multiple data formats, including DCM, CSV, etc. In such examples, users (e.g., technicians, engineers, etc.) may be able to control via user input (e.g., an input signal 110 of FIG. 1). the desired calibration sets in various formats. In various embodiments, multiple vehicle calibration sets may be imported concurrently, thereby offering flexibility. In other examples, the vehicle calibration sets may be imported consecutively if desired.

In some examples, the control module 102 may filter and/or sort the received vehicle calibration sets and/or the parameters therein. For example, a user may select an input option to filter one or more vehicle calibration sets. In doing so, the analysis of the vehicle calibration sets may be focused on specific subsets of calibrations for targeted comparisons, thereby allowing the user to hone in on particular calibration parameters that are of primary interest.

The control module 102 may be operable to perform a calibration comparison process. For example, the control module 102 may calculate (e.g., in substantially real time) one or more statistical relationships of corresponding vehicle parameters of the vehicle calibration sets received from the vehicle calibration database 104 and/or another suitable source. The statistical relationships (e.g., statistical measures) may include, for example, a mean, a standard deviation, a variance, and/or any other suitable computable relationship between parameters. In various embodiments, the statistical relationships computed may be defined by a user. In some examples, the control module 102 may automatically begin such calculations in response to receiving the vehicle calibration sets, in response to user input (e.g., via the signal 110, etc.).

In various embodiments, the control module 102 calculates anomaly scores associated with some or all of the received vehicle calibration sets. More specifically, the control module 102 may calculate anomaly scores for vehicle parameters in the vehicle calibration sets and/or sections (e.g., a collection of vehicle parameters) in the vehicle calibration sets. In doing so, the control module 102 may identify one or more vehicle parameter outliers in a set of vehicle calibrations as compared to corresponding vehicle parameters in other sets of the vehicle calibrations.

In the example of FIG. 1, the control module 102 may calculate the anomaly scores differently based on one or more conditions. For instance, and as further explained below, the control module 102 may calculate the anomaly scores for vehicle parameters in a scalar format in a different manner than vehicle parameters in a vector format or map format. In such examples, the control module 102 may identify the format type based on the data (e.g., a size of the data, etc.).

For example, the control module 102 may detect whether received vehicle calibration sets are in a scalar format or a vector or map format. Then, based on the type of format, the control module 102 may calculate the anomaly scores with different algorithms. For instance, in response to the vehicle calibration sets being in the scalar format, the control module 102 may calculate a distance for each corresponding vehicle parameter of each set of vehicle calibrations against a reference value and then calculate an anomaly score based on the distance, as further explained below. Alternatively, in response to the vehicle calibration sets being in the vector or map format, the control module 102 may calculate an anomaly score based on a cost function, as further explained below.

Additionally, the control module 102 may calculate the anomaly scores in a different manner based on whether a master vehicle calibration set is known. In such examples, the control module 102 may detect whether a vehicle calibration set is a master set based on user input (e.g., the set identified by a user), a label provided with the set of vehicle calibrations from the vehicle calibration database 104, etc.

For example, the control module 102 may determine that the received vehicle calibration sets include a master vehicle calibration set and one or more child vehicle calibration sets. In such examples, the control module 102 may treat the master vehicle calibration set as a reference set of vehicle calibrations for comparisons against the child vehicle calibration sets. In other examples, the received vehicle calibration sets may not include a master vehicle calibration set and/or the control module 102 may be unable to determine a master vehicle calibration set (e.g., if received). In such examples, the control module 102 may compute reference values and/or identify one of the vehicle calibration sets (e.g., among the same vehicle program or different vehicle programs) as being a reference set of vehicle calibrations, as further explained below.

Below are example operations taken by the control module 102 depending on whether a master vehicle calibration set is available and the type of data format (e.g., scalar, vector, or map). While the control module 102 is described as performing such operations, it should be appreciated that other example operations (e.g., computations, algorithms, etc.) may be taken if desired.

As referenced above, the control module 102 may calculate an anomaly score based on a determined distance for each corresponding vehicle parameter of each set of vehicle calibrations against a reference value if the vehicle calibration sets are in a scalar format. For example, if a master vehicle calibration set is available, the control module 102 calculates a distance for each corresponding vehicle parameter of each child vehicle calibrations set against a corresponding vehicle parameter of the master vehicle calibration set, and then calculates the anomaly score for that vehicle parameter based on the calculated distance. In various embodiments, the control module 102 may calculate a normalized value of the distance and then set the normalized value as the anomaly score for that vehicle parameter.

Alternatively, if a master vehicle calibration set is not available, the control module 102 may compute reference values. For example, the control module 102 calculates a mean for each corresponding vehicle parameter of the received vehicle calibration sets. Next, the control module 102 calculates a distance for each corresponding vehicle parameter of each set of vehicle calibrations against the calculated mean for that vehicle parameter, and then calculates the anomaly score for that vehicle parameter based on the calculated distance. Similar to above, the control module 102 may calculate a normalized value of the distance (relative to the mean) and then set the normalized value as the anomaly score for that vehicle parameter.

If, however, the vehicle calibration sets are in a vector or map format (e.g., a 2D or 3D format), the control module 102 may calculate an anomaly score based on a cost function, as referenced above. For example, if a master vehicle calibration set is available, the control module 102 calculates a gradient for each corresponding vehicle parameter of the vehicle calibration sets. In such examples, the gradient may be calculated in conventional manners.

Then, the control module 102 calculates one or more numerical relationships for each corresponding vehicle parameter of each child vehicle calibration set against a corresponding vehicle parameter of the master vehicle calibration set. For example, the control module 102 may calculate a Euclidean distance and a linear regression relationship for each corresponding child vehicle parameter against a corresponding master vehicle parameter (e.g., a reference parameter).

Next, the control module 102 implements a cost function relationship to calculate the anomaly score for each vehicle parameter. For example, the control module 102 may utilize a cost function that adds the gradient, the Euclidean distance, and the linear regression associated with a vehicle parameter to obtain the anomaly score. In various embodiments, each of the gradient, the Euclidean distance, and the linear regression may be weighted before the values are summed. For example, the gradient may be multiplied by a defined weighted value (e.g., a value between 0.1 and 0.9), the Euclidean distance may be multiplied by a defined weighted value (e.g., a value between 0.1 and 0.9), and the linear regression may be multiplied by a defined weighted value (e.g., a value between 0.1 and 0.9).

Alternatively, if a master vehicle calibration set is not available for a vector or map format analysis, the control module 102 may identify one of the vehicle calibration sets as a reference set of vehicle calibrations and then determine the anomaly score for each vehicle parameter based on that reference set. For example, the control module 102 calculates a gradient for each corresponding vehicle parameter of the vehicle calibration sets, as explained above.

Then, the control module 102 calculates one or more numerical relationships (e.g., a Euclidean distance and a linear regression relationship) for each corresponding vehicle parameter of each set of vehicle calibrations against a corresponding vehicle parameter of all other vehicle calibration sets. For instance, a Euclidean distance between one vehicle parameter in one calibration set relative to a corresponding vehicle parameter of another calibration set may be 20 and a Euclidean distance between that same vehicle parameter in the one calibration set relative to another corresponding vehicle parameter of yet another calibration set may be 30. The control module 102 then separately averages the Euclidean distances and the linear regression values for each parameter (e.g., a map) of a calibration set relative to the others to obtain a single Euclidean distance and a single linear regression value for that parameter of the calibration set. For example, with continued reference to the example above, the single Euclidean distance may be 25 (e.g., (20+30)/2).

Then, the control module 102 calculates a provisional anomaly score for each corresponding vehicle parameter based on a cost function, as explained above. For example, the cost function may add the gradient, the single (e.g., averaged) Euclidean distance, and the single (e.g., averaged) linear regression value associated with a vehicle parameter to obtain the provisional anomaly score. In various embodiments, each of the gradient, the Euclidean distance, and the linear regression may be weighted before the values are summed, as explained above. In such examples, the weighted values for when the master vehicle calibration set is unavailable and when the master vehicle calibration set is available may be different.

Next, the control module 102 determines which provisional anomaly score is the lowest for a given parameter across the calibration sets, and then sets that corresponding vehicle calibration set having the lowest provisional anomaly score as the reference set. For example, the control module 102 may set a value of the parameter corresponding to the lowest provisional anomaly score to zero.

Then, the control module 102 adjusts the other provisional anomaly scores for the corresponding vehicle parameters of the other calibration sets based on the reference set of vehicle calibrations. For instance, if the provisional anomaly scores are 18.5, 30.5, 48, the control module 102 sets a value of the parameter corresponding to the lowest provisional anomaly score (18.5) to zero. The control module 102 then substrates 18.5 from each of the other provisional anomaly scores for the corresponding vehicle parameters of the other calibration sets. In other words, the control module 102 adjusts the other provisional anomaly scores to 12 (e.g., 30.5-18.5) and 29.5 (e.g., 48-18.5). The adjusted provisional anomaly scores (e.g., 0, 12, 29.5) may then be provided as the anomaly scores.

Although the above example operations taken by the control module 102 are described with respect to determining an anomaly score specific to a parameter in a vehicle calibration set, it should be appreciated that similar computations may be implemented for a collection of vehicle parameters in a vehicle calibration set (e.g., could be tens of thousands per calibration set). For instance, each vehicle calibration set may include vehicle parameters divided into two or more sections. In such examples, an anomaly score for each section may be determined in a similar manner as explained above relative to an anomaly score for a vehicle parameter.

In various embodiments, the control module 102 may detect an anomaly associated with at least one vehicle parameter of a set of vehicle calibrations based on a calculate anomaly score for the vehicle parameter. For example, the control module 102 may compare the calculated anomaly score to a defined threshold (e.g., a single value, a range of values, etc.) and detect an anomaly if the anomaly score is greater than the defined threshold. As examples only, the defined threshold may be a percent (e.g., 10%, 12%, 15%, 17%, 20%, etc.) from the reference value employed as explained above.

Additionally, in some examples, the control module 102 may transmit at least one visualization to the display module 106 and/or another suitable module for displaying the visualization. The visualization may include a calculated anomaly score whether or not the anomaly score is associated with a detected anomaly. For example, the control module 102 may transmit the visualization with the anomaly score in response to the anomaly score being associated with a detected anomaly. In other examples, the control module 102 may transmit the visualization with the anomaly score even if an anomaly is not detected.

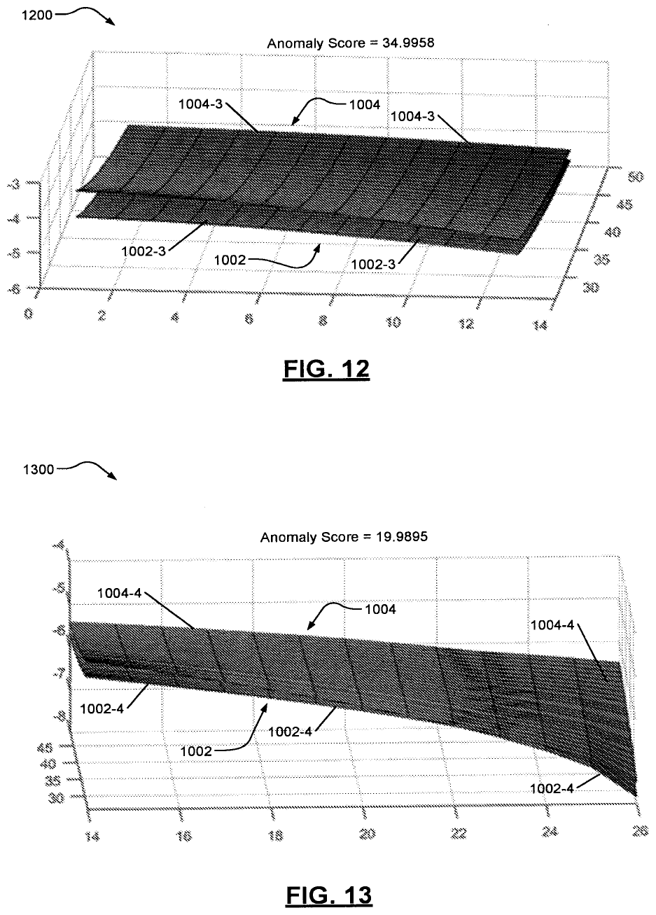

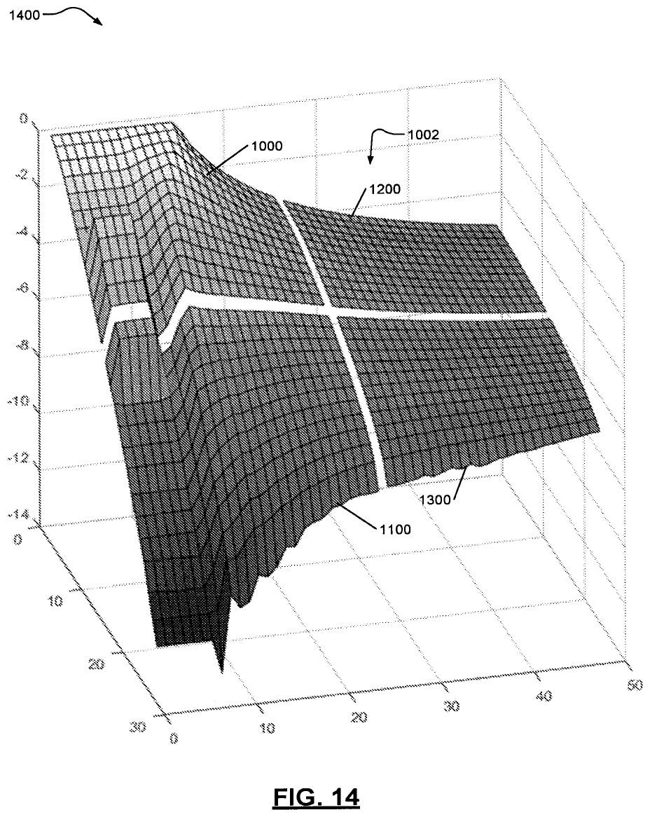

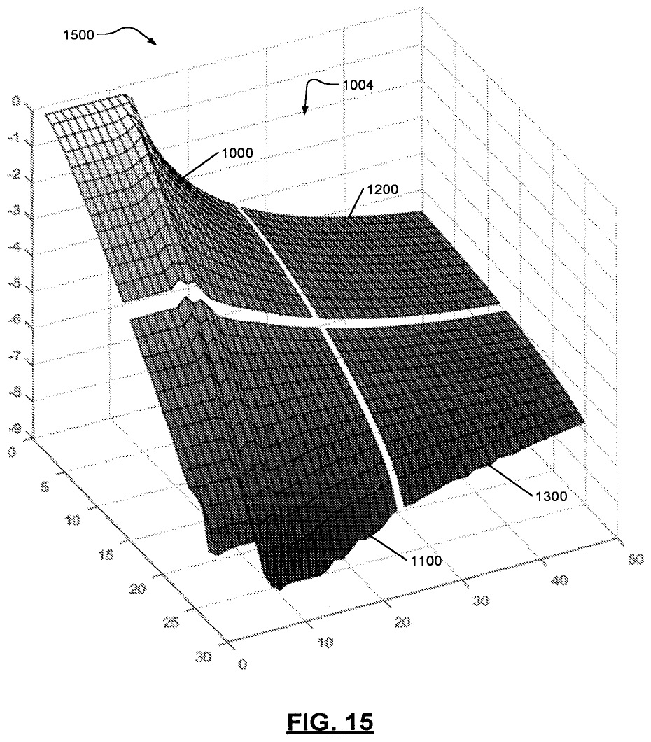

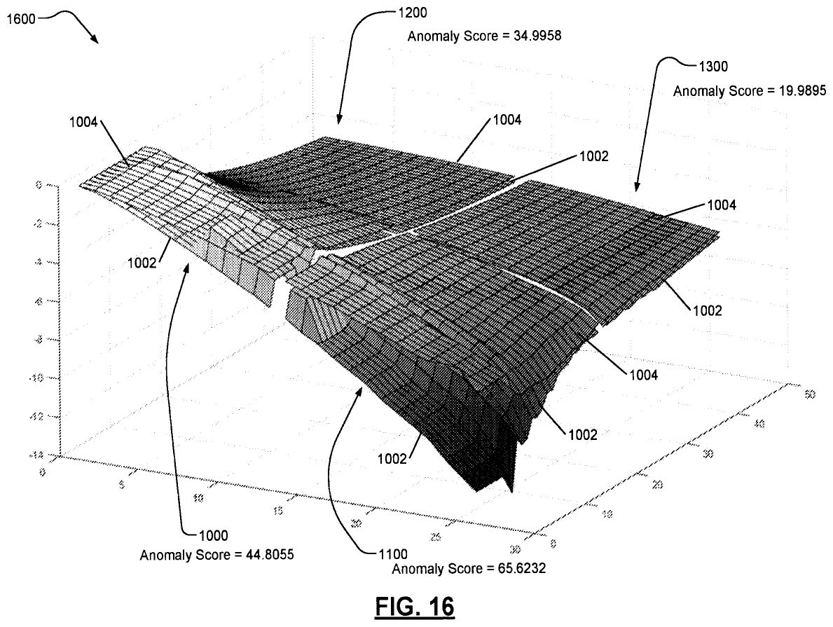

In various embodiments, the control module 102 may compile the computed data in different visual formats for user viewing. For instance, the control module 102 may leverage 2D and 3D visualization techniques to make complex calibration comparisons easily digestible and visually discernible for users. For example, the control module 102 may provide the visualization with one or more graphs charting anomaly scores, one or more tables charting anomaly scores, etc. As examples only, FIGS. 2-14 depict various graphs 200, 300, 400, 500, 600, 700, 800, 900, 1000, 1100, 1200, 1300, 1400, 1500, 1600 showing different visualizations of anomaly scores. In the examples of FIGS. 2-16, the vehicle parameter relets to battery current values.

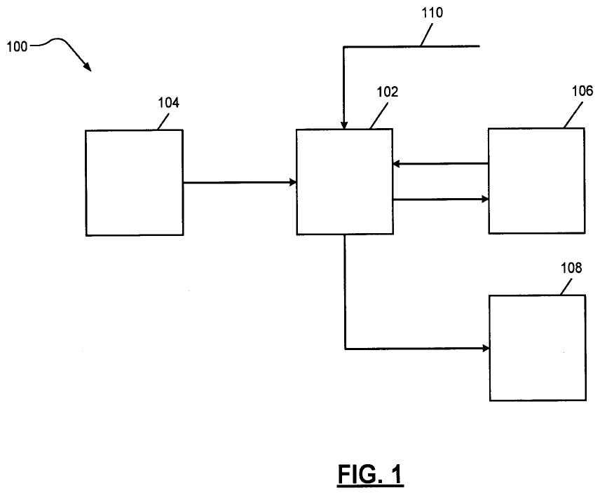

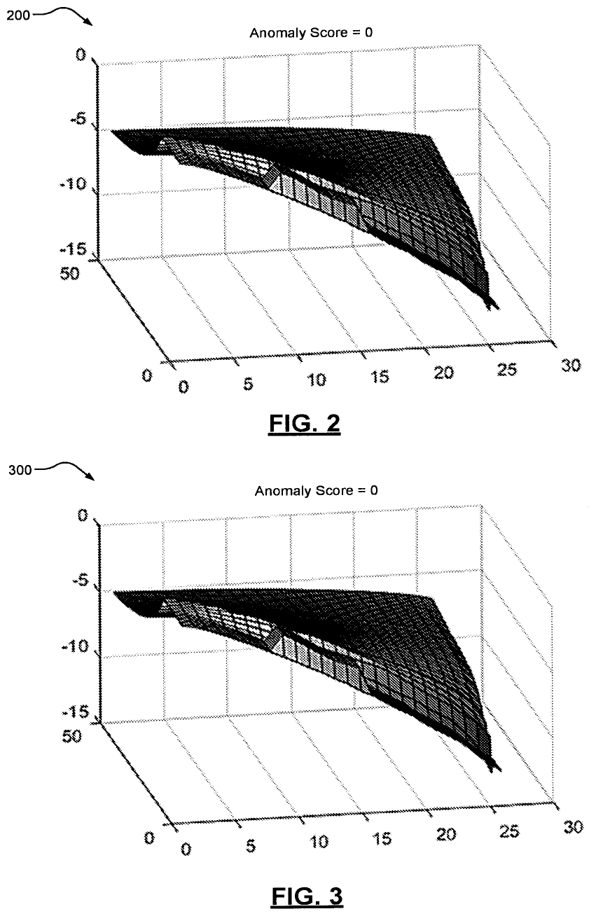

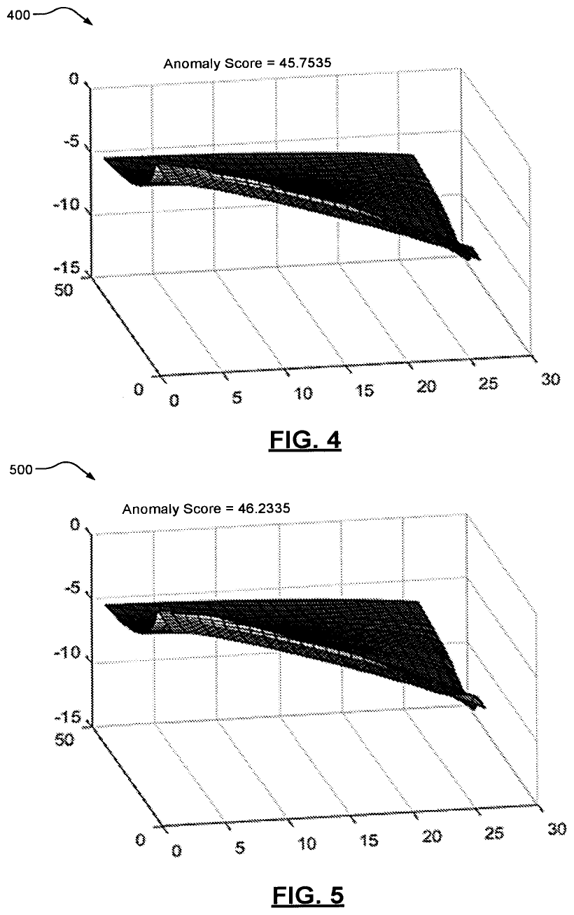

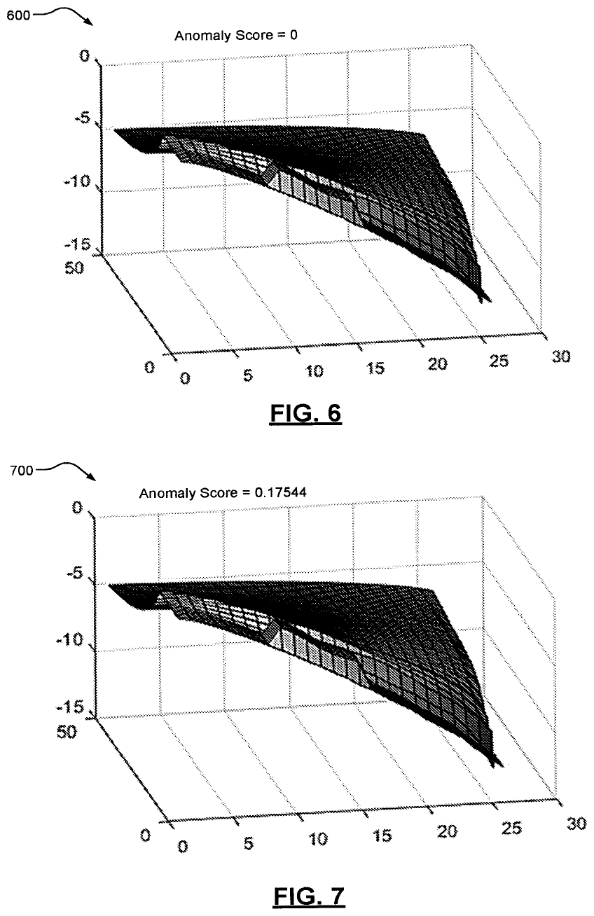

For example, the graphs 200, 300, 400, 500 of FIGS. 2-5 depict anomaly scores for a corresponding parameter across four different calibration sets when a master vehicle calibration set was employed as a reference. In such examples, the graph 200 of FIG. 2 depicts the parameter of the master vehicle calibration set with an anomaly score of zero (0). The graph 300 of FIG. 3 depicts the corresponding parameter of one child vehicle calibrations set (child #2) with an anomaly score of zero (0). As shown, the graph 300 of FIG. 3 is identical to the graph 200 of FIG. 2. The graph 400 of FIG. 4 depicts the corresponding parameter of another child vehicle calibrations set (child #3) with an anomaly score of 45.7535, and the graph 500 of FIG. 5 depicts the corresponding parameter of yet another child vehicle calibrations set (child #4) with an anomaly score of 46.2335. As shown, the graphs 400, 500 of FIGS. 4-5 are substantially different that the graph 200 of FIG. 2, thereby indicating parameter outliers (and possible anomalies). More specifically, the mid sections and bottom right sections of the graphs 400, 500 of FIGS. 4-5 are substantially different than corresponding sections of the graph 200 of FIG. 2.

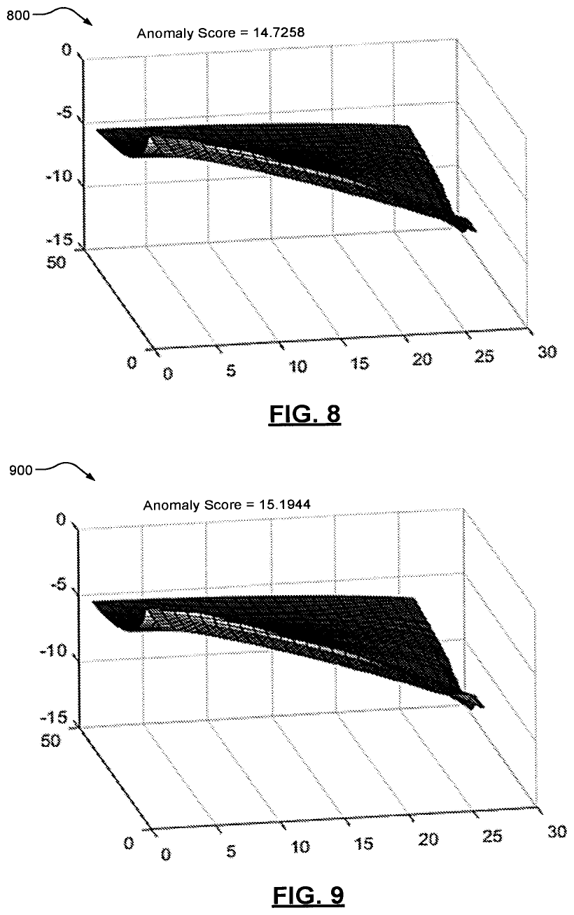

The graphs 600, 700, 800, 900 of FIGS. 6-9 depict anomaly scores for a corresponding parameter across four different calibration sets when a master vehicle calibration set was unavailable as a reference. In such examples, one of the calibration sets is set as a reference, as explained above. In this example, the graph 600 of FIG. 6 depicts the parameter of the calibration set that is utilized as the reference (e.g., the calibration set with the lowest provisional anomaly as explained above). As such, the anomaly score associated with the graph 600 is zero (0). The graph 700 of FIG. 7 depicts the corresponding parameter of another set of calibrations (set #2) with an anomaly score of 0.17544 (e.g., after adjustments as explained above). As shown, the graph 700 of FIG. 7 is nearly identical to the graph 600 of FIG. 6. The graph 800 of FIG. 8 depicts the corresponding parameter of another set of calibrations (set #3) with an anomaly score of 14.7258, and the graph 900 of FIG. 9 depicts the corresponding parameter of yet another set of calibrations (set #4) with an anomaly score of 15.1944. As shown, the graphs 800, 900 of FIGS. 8-9 are substantially different that the graph 600 of FIG. 6, thereby indicating parameter outliers (and possible anomalies).

In the examples of FIGS. 2-9, the parameter values of the different vehicle calibration sets are the same with the only difference being that a master calibration set is identified in the examples of FIGS. 2-5 and not in the examples of FIGS. 6-9. As shown, the control module 102 is able to calculate accurate anomaly scores and identify anomalies (e.g., the graphs 400, 500, 800, 900) regardless of whether a master calibration set (e.g., an initial reference set) is employed. This ensures efficacy in all practical scenarios, and demonstrates unparalleled versatility and innovation in addressing the industry's needs. For example, in some scenarios, a new vehicle program may be introduced that does not have a master calibration set and therefore no starting point. In such examples, the control module 102 can accurately calculate anomaly scores and identify anomalies without this starting point.

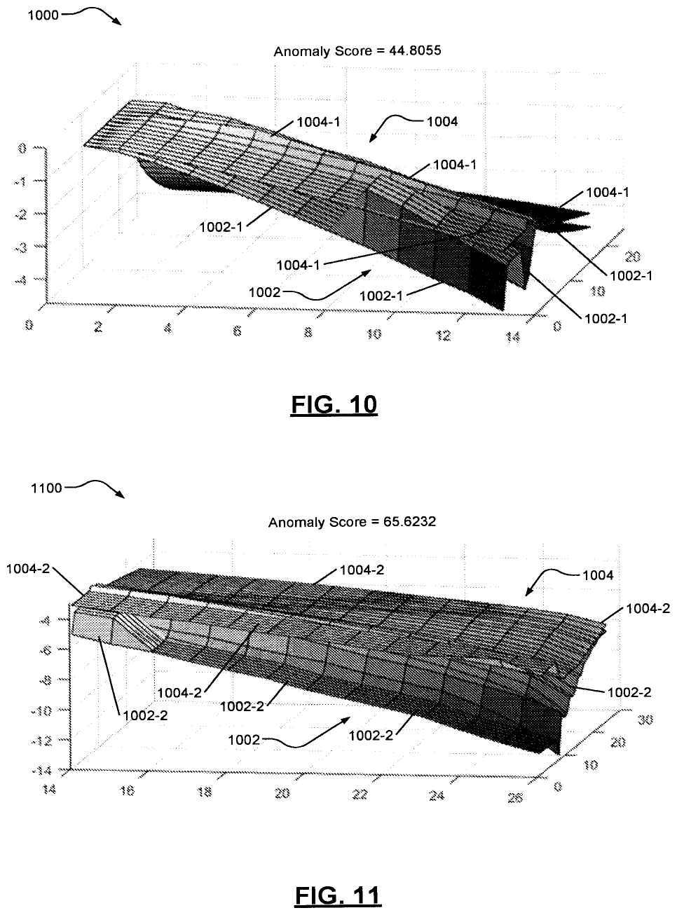

The graphs 1000, 1100, 1200, 1300 of FIGS. 10-13 depict anomaly scores for four different corresponding sections of two different calibration sets. With such configurations, a user can identify one or more particular sections causing issues (e.g., due to outlier parameter values in the particular sections), thereby providing a granular view of the analysis. Specifically, the graph 1000 depicts a first section 1002-1 of parameters for a master calibration set 1002 and a corresponding first section 1004-1 of parameters for a child calibration set 1004. The graphs 1100, 1200, 1300 depict similar characteristics for the master calibration set 1002 and the child calibration set 1004, but with the graph 1100 focusing on second sections 1002-2, 1004-2, the graph 1200 focusing on third sections 1002-3, 1004-3, and the graph 1300 focusing on fourth sections 1002-4, 1004-4. As shown, the master calibration set 1002 is generally below the child calibration set 1004.

Additionally, in the example of FIGS. 10-13, each section of the master calibration set 1002 has an anomaly score of zero (0), the first section 1004-1 of the child calibration set 1004 has an anomaly score of 44.8055, the second section 1004-2 of the child calibration set 1004 has an anomaly score of 65.5232, the third section 1004-3 of the child calibration set 1004 has an anomaly score of 34.9958, and the fourth section 1004-4 of the child calibration set 1004 has an anomaly score of 19.9895. In such examples, a particular section (e.g., the second section) can be identified as causing the most issues due to it having the highest anomaly score.

The graphs 1400, 1500, 1600 of FIGS. 14-16 depict other examples representations of the graphs 1000, 1100, 1200, 1300 of FIGS. 10-13. For example, the graph 1400 of FIG. 14 depicts the four sections of the graphs 1000, 1100, 1200, 1300 for the master calibration set 1002, and the graph 1500 of FIG. 15 depicts the four sections of the graphs 1000, 1100, 1200, 1300 for the child calibration set 1004. Additionally, the graph 1600 of FIG. 16 depicts the four sections of the graphs 1000 (anomaly score of 44.8055), 1100 (anomaly score of 65.5232), 1200 (anomaly score of 34.9958), 1300 (anomaly score of 19.9895) for both the master calibration set 1002 and the child calibration set 1004.

With continued reference to FIG. 1, the control module 102 may transmit at least one visualization with at least one table charting various variables and/or the previously computed statistical relationships. In such examples, the control module 102 may transmit such data to the display module 106 and/or another suitable module for displaying the table. For example, the table may include various parameter values (in different formats, such as scalar, vector, and map) for difference calibration sets of the same vehicle program. In other examples, the table may include various parameter values (in different formats, such as scalar, vector, and map) for different vehicle programs.

Table 1 below is one example illustration of data in a visualization that may be displayed on the display module 106 for a user. As shown below, Table 1 includes corresponding parameters for difference calibration sets (Cal Set 1, Cal Set 2, . . . . Cal Set 59, Cal Set 60) of the same vehicle program (VP1). In this example, the parameters are shown in different formats, such as scalar, vector, and map. In various embodiments, the calibration set (Cal Set 1) may be a master calibration set and the other calibration sets (Cal Set 2, . . . . Cal Set 59, Cal Set 60) may be child calibration sets associated with the master calibration set in one vehicle program. While Table 1 shows sixty (60) calibration sets for the vehicle program (VP1), it should be appreciated that more or less may be implemented.

As shown below, the scalar parameters are represented by “Value”, the scalar parameters are represented by arrows, and the map parameters are represented by grids. In such examples, each scalar parameter (Value) is a single value (e.g., 50, 80, 52, 45, etc.), each vector parameter may be different values along an axis, and each map parameter may be different values along two axes. For example, a vector parameter may include x-axis values (e.g., battery current values, etc.) of 1000, 2000, 3000, 4000 and corresponding parameter values (e.g., torque values, etc.) of 10, 20, 30, 40, respectively, for the x-axis values. A map parameter may include x-axis values (e.g., battery current values, etc.) of 1000, 2000, 3000, 4000, y-axis values (e.g., vehicle speed values, etc.) of 100, 200, 300, 400, and sixteen parameter values for the grid of x and y axes values.

Additionally, each scalar parameter (Value) in Table 1 may be any suitable user requested statistical measure. For example, any one of the scalar parameters may be a mean, a mean difference, a standard deviation, a co-variance, a percentage difference, a relative error, a maximum difference, a minimum difference, an anomaly score, an absolute raw value, etc. Such statistical relationships may be computed by the control module 102 as explained above.

TABLE 1

| | Cal Set 1 | Cal Set 2 | | Cal Set 4 | Cal Set 5 |
|---|---|---|---|---|---|
| | (VP1) | (VP1) | . . . | (VP1) | (VP1) |
| Scalar 1 | Value | Value | . . . | Value | Value |
| (example | | | | | |
| parameter) | | | | | |
| Scalar 2 | Value | Value | . . . | Value | Value |
| (example | | | | | |
| parameter) | | | | | |
| Vector 3 | [symbol] | [symbol] | . . . | [symbol] | [symbol] |
| (example | | | | | |
| parameter) | | | | | |
| Map 4 | \|__ | \|__ | . . . | \|__ | \|__ |
| (example | | | | | |
| parameter) | | | | | |
| . . . | . . . | . . . | . . . | . . . | . . . |
| Scalar | Value | Value | . . . | Value | Value |
| 2000 | | | | | |
| (example | | | | | |
| parameter) | | | | | |

Table 2 below is another example illustration of data in a visualization that may be displayed on the display module 106 for a user. As shown below, Table 2 includes various variants (Variant 1, Variant 2, . . . . Variant 5) for different vehicle programs (VP1, VP2, VP30). In such examples, each variant may represent different parameters in different formats, such as scalar, vector, and map for different vehicle calibration sets. Similar to Table 1 above, the scalar parameters in Table 2 are represented by “Value”, the scalar parameters in Table 2 are represented by arrows, and the map parameters in Table 2 are represented by grids.

In this example, the total number of variants for a single vehicle program is five and are differentiated by vehicle features (e.g., options, etc.), such as rear wheel drive (RWD), all-wheel drive (AWD), long range battery, etc. Additionally, in this example, the total number of vehicle programs. While the total number of variants for a vehicle program and the total number of vehicle programs are specified as being five and thirty, it should be appreciated that such values are examples only and that more or less variants per vehicle program and/or vehicle programs may be employed if desired depending on, for example, the available vehicle features (e.g., options, etc.), the number of manufacturer variants, the number of manufacturer vehicle program, etc.

In various embodiments, Table 2 may represent an analysis for a motor calibration control module. In other examples, the same or different table (e.g., format, variants, etc.) may be used for a battery calibration control module, an inverter calibration control module, a diagnostics calibration control module, etc. Further, and as shown below in Table 2, any combination of variants and vehicle programs can be compared to find one or more possible anomalies, as many sub-features of one vehicle (e.g., of one vehicle program) may have similar calibrations as sub-features of another vehicle (e.g., of another vehicle program).

TABLE 2

| | Variant 1 | Variant 2 | | Variant 4 | Variant 5 |
|---|---|---|---|---|---|
| | (VP1) | (VP2) | . . . | (VP29) | (VP30) |
| Scalar 1 | Value | Value | . . . | Value | Value |
| (example | | | | | |
| parameter) | | | | | |
| Scalar 2 | Value | Value | . . . | Value | Value |
| (example | | | | | |
| parameter) | | | | | |
| Vector 3 | [symbol] | [symbol] | . . . | [symbol] | [symbol] |
| (example | | | | | |
| parameter) | | | | | |
| Map 4 | \|__ | \|__ | . . . | \|__ | \|__ |
| (example | | | | | |
| parameter) | | | | | |
| . . . | . . . | . . . | . . . | . . . | . . . |
| Scalar 2000 | Value | Value | . . . | Value | Value |
| (example | | | | | |
| parameter) | | | | | |

With continued reference to FIG. 1, the control module 102 may modify one or more vehicle parameters of a vehicle calibration set. For example, in response to detecting an anomaly associated with a vehicle parameter based on an anomaly score (as explained herein), the control module 102 may automatically modify that a value of that vehicle parameter. In such examples, the control module 102 may modify the vehicle parameter to a defined value (e.g., as defined by a user, etc.).

For example, once the anomaly is detected and the anomaly is above a defined threshold set by a user, the control module 102 may implement an automated autocorrect feature to fix errors in the vehicle parameters (calibrations) as compared to reference calibrations. In such examples, when sections of a calibration map (e.g., as illustrated in FIGS. 10-16) have different anomaly scores, the control module 102 may implement the automated autocorrect feature on the sections which are above the defined threshold set by the user, such that only these sections can be autocorrected and automated across all the thousands of calibration parameters.

In other examples, the control module 102 may modify one or more vehicle parameters of a vehicle calibration set based on user input. For example, the control module 102 may transmit (e.g., to the display module 106) calculated anomaly scores associated with vehicle parameters and/or sections in the form of graphs (e.g., any one or more of the graphs of FIGS. 2-16), tables, and/or another visualization. In other examples, the control module 102 may transmit parameters values and statistical relationships (e.g., Table 1, Table 2, etc.) along with anomaly scores.

A user may then analyze the presented data and determine whether a modification is desired. For example, in some scenarios, it may be desired to have a parameter value outlier or a modification to one parameter may affect another parameter. As such, the user may decide if modification of the vehicle parameter is desirable. In such examples, the display module 106 and/or another suitable device may transmit a signal (via user input) to the control module 102 instructing the control module 102 to modify the vehicle parameter (and possibly to a defined value). Then, the control module 102 may modify the vehicle parameter in response to the received signal.

In other examples, a user may prefer to modify a vehicle parameter of the vehicle calibration set even if an anomaly associated with the vehicle parameter is not detected. For example, in cases where the vehicle parameter may be somewhat of an outlier but is not a problem, the user may provide user input to the control module 102 to modify the vehicle parameter. In such examples, the modification, while not necessary to correct a problem, may help achieve better (e.g., optimize) vehicle performance.

In various embodiments, the control module 102 may transmit one or more vehicle calibration sets to the vehicle control module 108 of FIG. 1. For example, the control module 102 may transmit vehicle calibration sets with previously modified vehicle parameter(s) as explained above. In other examples, the control module 102 may transmit vehicle calibration sets with unmodified vehicle parameter(s) if no modifications are necessary. In such examples, the vehicle calibrations may be flashed into memory of the vehicle control module 108 and/or provided to the vehicle control module 108 in another suitable manner.

In some examples, the control module 102 may transmit vehicle calibration sets at different times. For example, the control module 102 may transmit (e.g., push) vehicle calibration sets including modified vehicle parameter(s) during the manufacturing process of the vehicle. In other examples, anomalies associated with vehicle parameter(s) may not be apparent until after the vehicle is manufactured. In such examples, the control module 102 may transmit (e.g., push) vehicle calibration sets including modified vehicle parameter(s) to the vehicle control module 108 in a post-manufactured vehicle (e.g., during a recall process, OTA updates, etc.)

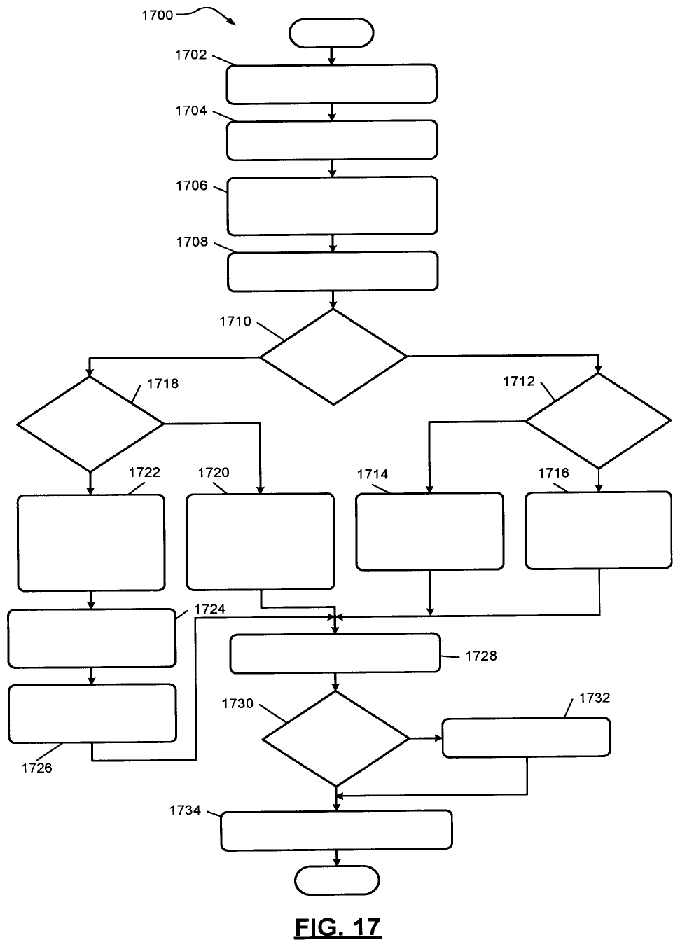

FIGS. 17-22 illustrate example control processes 1700, 1800, 1900, 2000, 2100, 2200 employable by the control module 102 of FIG. 1 for detecting anomalies in vehicle calibrations sets, generating statistical visualizations of the vehicle calibrations sets, and/or modifying vehicle calibrations. Although the example control processes 1700, 1800, 1900, 2000, 2100, 2200 are described in relation to the system 100 of FIG. 1 including the control module 102, any one of the control processes 1700, 1800, 1900, 2000, 2100. 2200 may be employable by any suitable system.

As shown in FIG. 17, control begins at 1702 where the control module 102 receives or imports vehicle calibration sets as explained herein. For example, the vehicle calibration sets includes vehicle parameters having the same or different data formats (e.g., DCM, CSV, etc.). Control then proceeds to 1704 where the control module 102 may optionally filter and/or sort data in the received vehicle calibration sets as explained above. Control then proceeds to 1706 and 1708.

At 1706, the control module 102 may optionally compute or otherwise determine one or more statistical relationships (e.g., statistical measures such as a mean, a standard deviation, a variance, and/or any other suitable computable relationship between parameters.) for the vehicle calibration sets. In such examples, the control module 102 may automatically begin such calculations in response to receiving the vehicle calibration sets, in response to filtering, in response to user input, etc.

At 1708, the control module 102 detects a data type of one or more of the received vehicle calibration sets. For example, and as explained above, the control module 102 may detect whether received vehicle calibration sets are in a scalar format or a vector format or map format. In such examples, the control module 102 may identify the format type based on the data (e.g., a size of the data, etc.), based on labeled data, etc. Control then proceeds to 1710.

At 1710, the control module 102 determines whether the detected vehicle calibration sets are in a scalar format. If yes, control proceeds to 1712. If, however, the vehicle calibration sets are not a scalar format (e.g., are instead in a vector format or map format), control proceeds to 1718.

At 1712, the control module 102 determines whether a master calibration set exists from the vehicle calibration sets. For example, and as explained above, the control module 102 may detect whether one of the vehicle calibration sets is a master calibration set based on user input (e.g., the set identified by a user), a label provided with the set of vehicle calibrations, etc.

If the master calibration set does exist, control proceeds to 1714 where the control module 102 calculates anomaly scores based on the existing master calibration set as explained herein. Control then proceeds to 1728. If, however, the master calibration set does not exist or cannot be identified, control proceeds to 1716 where the control module 102 calculates anomaly scores based on all of the vehicle calibration sets as explained herein. Control then proceeds to 1728.

At 1718, the control module 102 determines whether a master calibration set exists from the vehicle calibration sets, as explained herein. If the master calibration set does exist and the data is not a scalar format (e.g., instead in a vector format or map format), control proceeds to 1720. At 1720, the control module 102 calculates an anomaly score based on the master calibration set and weight factors, as explained herein. Control then proceeds to 1728.

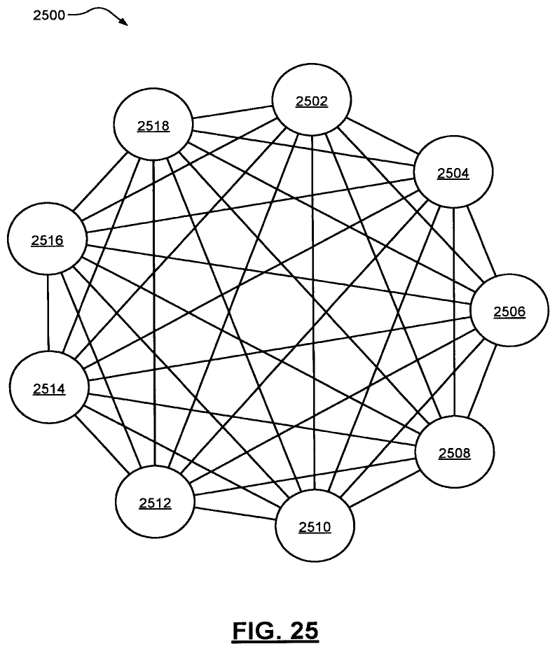

If, however, the master calibration set does not exist and the data is not a scalar format (e.g., instead in a vector format or map format), control proceeds to 1722. At 1722, the control module 102 calculates anomaly scores (e.g., provisional anomaly scores) based on all of the vehicle calibration sets and weight factors, as explained herein. For example, the control module 102 can calculate a provisional anomaly score for each corresponding vehicle parameter of all of the vehicle calibration sets based on a cost function. As such, the provisional anomaly score for a vehicle parameter of each vehicle calibration set may be referenced against the corresponding vehicle parameter of the other vehicle calibration sets. FIG. 25 depicts one example diagram 2500 showing such interaction between nine different vehicle calibration sets 2502, 2504, 2506, 2508, 2510, 2512, 2514, 2516, 2518. While the diagram 2500 of FIG. 25 includes nine vehicle calibration sets, it should be appreciated more or less vehicle calibration sets may be employed (e.g., six vehicle calibration sets, twelve vehicle calibration sets, 24 vehicle calibration sets, etc.).

With continued reference to FIG. 17, control then proceeds to 1724 and 1726. At 1724, the control module 102 sets the vehicle calibration set having the lowest provisional anomaly score as a reference set. Then at 1726, the control module 102 adjusts the other calculated provisional anomaly scores based on the reference set, as explained herein. Control then proceeds to 1728.

At 1728, the control module 102 generates and outputs one or more visualizations with the calculated anomaly scores (from 1714 or 1716 or 1720 or 1726) and/or the computed statistical relationships (from 1706). For example, and as explained herein, the control module 102 may compile the computed data in different visual formats for user viewing, such as graphs, tables, etc. Then, the control module 102 may transmit the graphs, tables, etc. to the display module 106 of FIG. 1 and/or another suitable module for displaying the visualization(s), as explained herein. Control then proceeds to 1730.

At 1730, the control module 102 determines whether any input is received. For example, a user may analyze the data provided to the display module 106 and determine whether a parameter modification is desired, as explained herein. If so, the user may transmit a user input to the control module 102 (e.g., via the display module 106 and/or another suitable device. The user input may instruct the control module 102 to modify one or more specific vehicle parameters of specific calibration sets. If no user input is received, control proceeds to 1734.

If, however, the control module 102 does receive a user input, control proceeds to 1732 where the control module 102 corrects or modifies the specific vehicle parameters. Control then proceeds to 1734.

At 1734, the control module 102 transmits one or more vehicle calibration sets to a vehicle control module (e.g., the vehicle control module 108 of FIG. 1). For example, and as explained above, the control module 102 may transmit vehicle calibration sets with previously modified vehicle parameter(s) (e.g., at 1732), as explained above. In other examples, the control module 102 may transmit vehicle calibration sets with unmodified vehicle parameter(s) if no modifications are necessary. In such examples, the vehicle calibrations may be flashed into memory of the vehicle control module 108 and/or provided to the vehicle control module 108 in another suitable manner. Control may then end.

In various embodiments, the control module 102 may optionally compare the calculated anomaly scores (from 1714 or 1716 or 1720 or 1726) to one or more defined thresholds to detect anomalies. This step may take place before or after the control module 102 generates and outputs the one or more visualizations. In some examples, the control module 102 may only generate and output the one or more visualizations if one or more anomalies are detected.

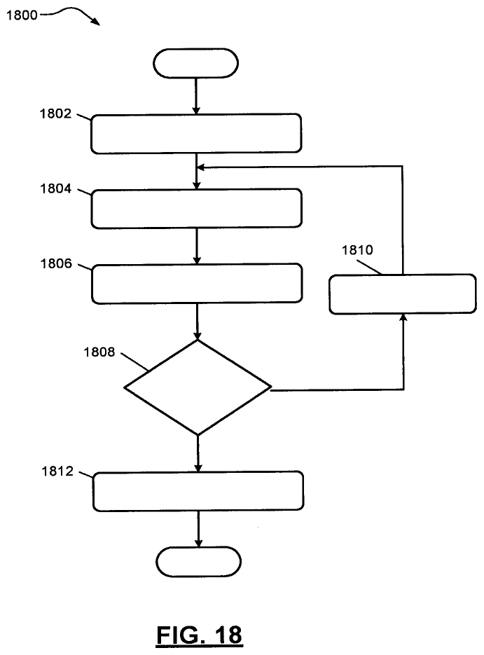

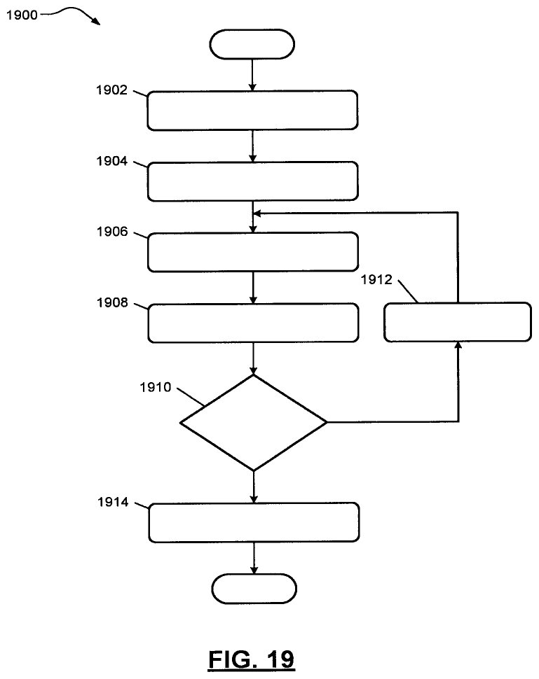

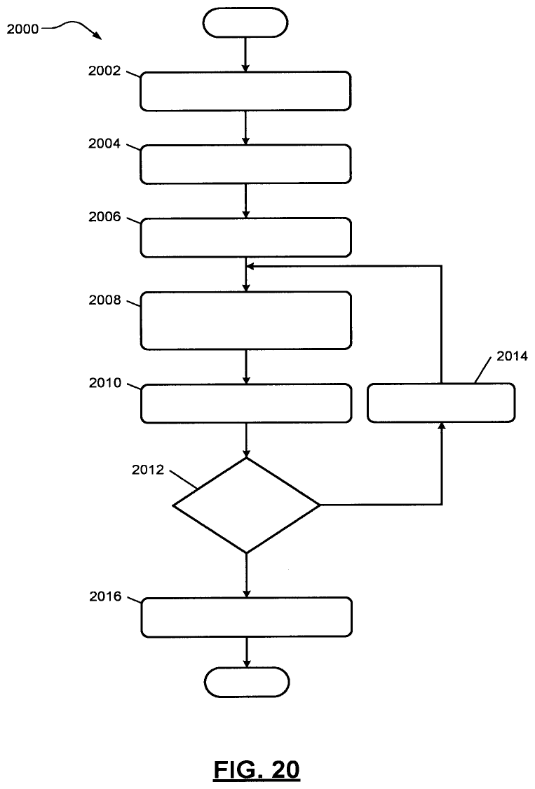

The control process 1800 of FIG. 18 depicts one example implementation of step 1714 of FIG. 17, where the control module 102 calculates anomaly scores for scalar data based on an existing master calibration set. As shown, control begins at 1802 where the control module 102 selects one of the received child calibration sets. Control then proceeds to 1804 and 1806.

At 1804, the control module 102 calculates a distance for each vehicle parameter of the selected child calibration set against corresponding vehicle parameters of the master calibration set, as explained herein. Then at 1806, the control module 102 calculates the anomaly score(s) for the child vehicle parameter(s) based on the calculated distance(s). As explained herein, the control module 102 may calculate the anomaly score(s) based on normalized distances. Control then proceeds to 1808.

At 1808, the control module 102 determines whether any more child calibration sets remain. If so, control proceeds to 1810 where the control module 102 selects the next child calibration set. Control then returns to 1804 and 1806 where anomaly score(s) for the next calibration set are calculated. If, however, no more child calibration sets remain at 1808, control proceeds to 1812 where the control module 102 outputs or otherwise makes available the calculated anomaly score(s). Control may then end.

The control process 1900 of FIG. 19 depicts one example implementation of step 1716 of FIG. 17, where the control module 102 calculates anomaly scores for scalar data based on other vehicle calibration sets (e.g., no master calibration set exists or is identified) as explained herein. As shown, control begins at 1902 where the control module 102 calculates a mean of all calibration sets. For example, and as explained above, the control module 102 may calculate a mean for each corresponding vehicle parameter of the vehicle calibration sets. Control then proceeds to 1904 where the control module 102 selects one of the received child calibration sets. Control then proceeds to 1906 and 1908.

At 1906, the control module 102 calculates a distance for each vehicle parameter of the selected child calibration set against a corresponding calculated mean, as explained herein. Then at 1908, the control module 102 calculates the anomaly score(s) for the vehicle parameter(s) based on the calculated distance(s). As explained herein, the control module 102 may calculate the anomaly score(s) based on normalized distances. Control then proceeds to 1910.

At 1910, the control module 102 determines whether any more calibration sets remain. If so, control proceeds to 1912 where the control module 102 selects the next calibration set. Control then returns to 1906 and 1908 where anomaly score(s) for the next set are calculated. If, however, no more calibration sets remain at 1910, control proceeds to 1914 where the control module 102 outputs or otherwise makes available the calculated anomaly score(s). Control may then end.

The control process 2000 of FIG. 20 depicts one example implementation of step 1720 of FIG. 17, where the control module 102 calculates anomaly scores for vector or map data based on an existing master calibration set. As shown, control begins at 2002 where the control module 102 selects defined weight factors (e.g., including various defined weights). Control then proceeds to 2004, where the control module 102 calculates a gradient for each corresponding vehicle parameter of the vehicle calibration sets, as explained herein. Control then proceeds to 2006, where the control module 102 selects one of the received child calibration sets. Control then proceeds to 2008 and 2010.

At 2008, the control module 102 calculates numerical relationships for each corresponding vehicle parameter of the child calibration set relative to the master calibration set. For example, and as explained above, the control module 102 may calculate a Euclidean distance and a linear regression relationship for each corresponding vehicle parameter of each child calibration set against a corresponding vehicle parameter of the master calibration set.

At 2010, the control module 102 calculates anomaly score(s) for the vehicle parameter(s) in the selected calibration set. For example, and as explained above, the control module 102 may calculate an anomaly score by implementing a defined cost function that sums the calculated gradient, the calculated Euclidean distance, and the calculated linear regression, with each being weighted according to the defined weight factors. Control then proceeds to 2012.

At 2012, the control module 102 determines whether any more child calibration sets remain. If so, control proceeds to 2014 where the control module 102 selects the next child calibration set. Control then returns to 2008 and 2010 where anomaly score(s) for the next set are calculated. If, however, no more calibration sets remain at 2012, control proceeds to 2016 where the control module 102 outputs or otherwise makes available the calculated anomaly score(s). Control may then end.

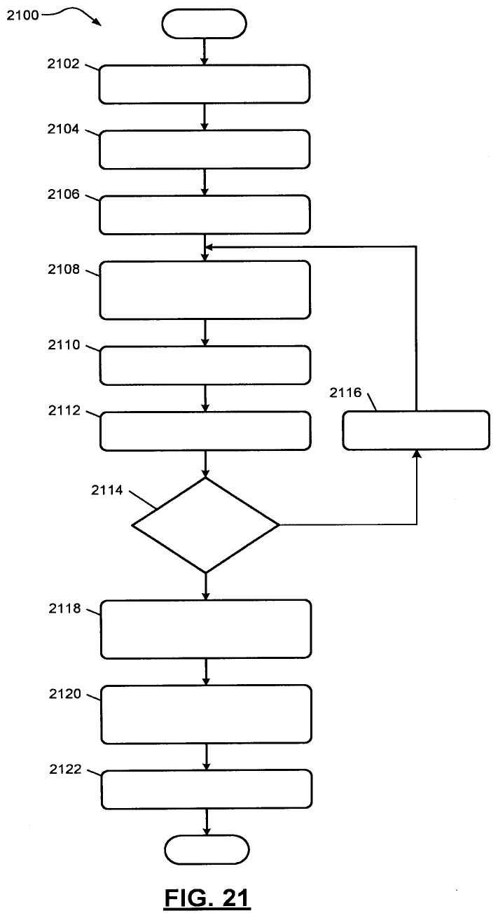

The control process 2100 of FIG. 21 depicts one example implementation of step 1722 of FIG. 17, where the control module 102 calculates anomaly scores for vector or map data when no master calibration set exists or is identified. As shown, control begins at 2102 and 2104 where the control module 102 selects defined weight factors (e.g., including various defined weights). In various embodiments, the defined weight factors selected at 2102 may be different values than selected at 2002 of FIG. 20. Control then proceeds to 2104,

At 2104, the control module 102 calculates a gradient for each corresponding vehicle parameter of the vehicle calibration sets, as explained herein. Control then proceeds to 2106, where the control module 102 selects one of the received calibration sets. Control then proceeds to 2108, 2110, 2112.

At 2108, the control module 102 calculates numerical relationships (e.g., a Euclidean distance, a linear regression relationship, etc.) for each corresponding vehicle parameter of the calibration set relative to each other calibration set. At 2110, the control module 102 calculates an average of each calculated numerical relationship (e.g., an average of all Euclidean distance values for the selected vehicle calibration set, an average of all linear regression values for the selected vehicle calibration set, etc.). At 2112,

At 2112, the control module 102 calculates anomaly score(s) for the vehicle parameter(s) in the selected calibration set. For example, and as explained above, the control module 102 may calculate an anomaly score (e.g., a provisional anomaly score) by implementing a defined cost function that sums the calculated gradient, the calculated average Euclidean distance, and the calculated average linear regression, with each being weighted according to the defined weight factors (selected at 2102). Control then proceeds to 2114.

At 2114, the control module 102 determines whether any more calibration sets remain. If so, control proceeds to 2116 where the control module 102 selects the next calibration set. Control then returns to 2108, 2110, 2112 where anomaly score(s) for the next set are calculated. If, however, no more calibration sets remain at 2114, control proceeds to 2118, 2120, 2122.

At 2118, the control module 102 sets the vehicle calibration set having the lowest (e.g., provisional) anomaly score as a reference set. Then, at 2120, the control module 102 adjusts the other calculated (e.g., provisional) anomaly scores based on the reference set, as explained herein. Control then proceeds to 2122, where the control module 102 outputs or otherwise makes available the calculated anomaly score(s). Control may then end.

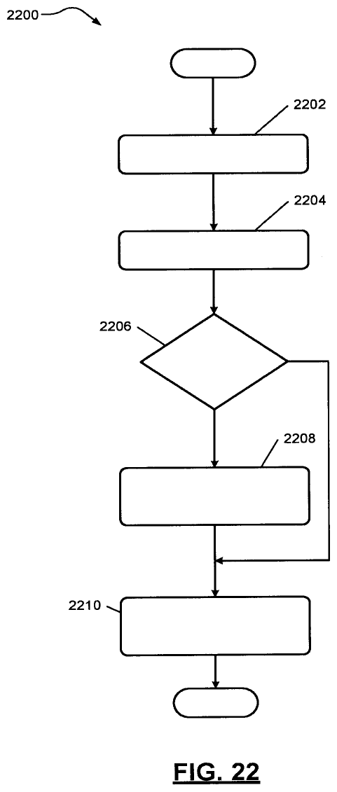

The control process 2200 of FIG. 22 depicts one example implementation of automatically autocorrecting vehicle parameters. In various embodiments, the control process 2200 may be implemented in conjunction with the control process 1700, such as for example before or after step 1728 of FIG. 17. In other examples, the control process 2200 may replace steps 1728, 1730, 1732, 1734 of FIG. 17.

As shown, control begins at 2202 where the control module 102 receives a defined anomaly threshold. In various embodiments, the defined anomaly threshold may be user set. As such, the control module 102 may receive the threshold via user input. Control then proceeds to 2204.

At 2204, the control module 102 receives a reference calibration set having, for example, various calibrations (e.g., parameters). In various embodiments, the reference calibrations may be user defined. For example, the reference calibrations may be a master calibration set or another suitable reference set, as explained herein. Control then proceeds to 2206.

At 2206, the control module 102 determines any detected anomaly has a score greater than the defined anomaly threshold. If yes at 2206, control proceeds to 2208 where the control module 102 autocorrects calibrations (e.g., calibrations in a particular section) corresponding to the detected anomaly. In such examples, the control module 102 may set the calibrations to equal the reference calibrations. control proceeds to 2210. If no at 2206, control proceeds to 2210, where the control module 102 transmits one or more vehicle calibration sets to a vehicle control module (e.g., the vehicle control module 108 of FIG. 1), as explained herein. Control may then end.

In various embodiments, subsequent to the detection and rectification of an anomaly, the updated calibration(s) can be transmitted to a manufacturing facility for making one or more vehicles. This enables the integration of the new calibration(s) with the software, facilitating the flashing process. Furthermore, in instances where a vehicle is in a post-production stage and already is in the possession of the customer, the updated calibration(s) can be delivered via Over-The-Air (OTA) technology. This methodology serves to obviate the necessity for a physical recall of the vehicle, thereby effecting savings in both time and financial resources.

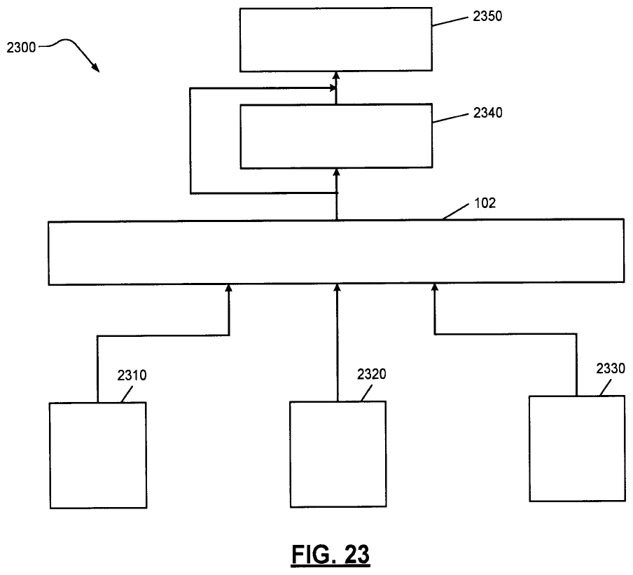

For example, FIG. 23 depicts a system 2300 including the control module 102 of FIG. 1. As shown, the control module 102 receives vehicle calibration sets (e.g., master calibration sets (if applicable), child calibration sets, etc.) relating to a vehicle program (1) 2310, a vehicle program (2) 2320, and a vehicle program (N) 2330. In such examples, the N may be any suitable positive value, such as thirty, thirty-five, forty, etc. In various embodiments, each vehicle calibration set may be generated according to multiple process stages, such as requirements engineering, system design and development, software development, software integration, function integration, and function calibration.

Then, the control module 102 may detect and subsequent rectify one or more anomalies associated with calibration(s) of a particular calibration set to the vehicle program (1) 2310, the vehicle program (2) 2320, and/or the vehicle program (N) 2330, as explained herein. Next, the control module 102 may transmit the new/rectified calibration(s) to various locations. For example, and as shown in FIG. 23, the control module 102 may transmit the new/rectified calibration(s) to a manufacturing facility 2340 for making one or more vehicles. Additionally and/or alternatively, the control module 102 may transmit the new/rectified calibration(s) to a post-production vehicle 2350 in the possession of a customer. In such examples, the control module 102 may transmit the new/rectified calibration(s) via OTA technology.

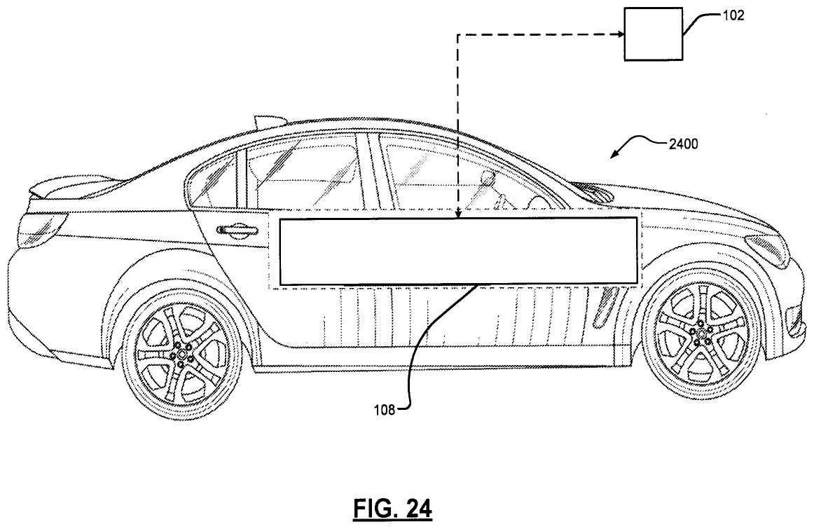

For example, FIG. 24 depicts a vehicle 2400 including the vehicle control module 108 of FIG. 1. In the example of FIG. 24, the vehicle control module 108 is in communication with the control module 102 of FIG. 1 for receiving calibrations, including possible new/rectified calibration(s). In various embodiments, the vehicle 2400 may be a post-production vehicle in the possession of a customer. In such examples, the vehicle control module 108 may receive the new/rectified calibration(s) via OTA technology. In other examples, the vehicle 2400 may be a vehicle in a manufacturing facility (e.g., in the process of being manufactured). In such examples, the new/rectified calibration(s) may be flashed into memory associated with the vehicle control module 108, as explained herein.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A method for detecting anomalies in vehicle calibrations sets, the method comprising:
receiving a plurality of vehicle calibration sets, each vehicle calibration set including corresponding vehicle parameters;
calculating, for each vehicle parameter of each vehicle calibration set, an anomaly score;
detecting an anomaly associated with at least one vehicle parameter of a vehicle calibration set of the plurality of vehicle calibration sets based on the anomaly score for the vehicle parameter and a defined threshold;
in response to detecting the anomaly, modifying the vehicle parameter of the vehicle calibration set; and
transmitting the vehicle calibration set including the modified vehicle parameter to a vehicle control module associated with a vehicle for controlling at least one component of the vehicle.

2. The method of claim 1, wherein:
the plurality of vehicle calibration sets includes a master vehicle calibration set and one or more child vehicle calibration sets; and
calculating the anomaly score includes:
calculating a gradient for each corresponding vehicle parameter of the plurality of vehicle calibration sets;
calculating one or more numerical relationships for each corresponding vehicle parameter of each child vehicle calibration set against a corresponding vehicle parameter of the master vehicle calibration set; and
calculating the anomaly score based on a cost function, a weighted value of the gradient, and weighted values of the one or more numerical relationships.

3. The method of claim 2, wherein the one or more numerical relationships include a Euclidean distance and a linear regression.

4. The method of claim 1, wherein calculating the anomaly score includes:
calculating a gradient for each corresponding vehicle parameter of the plurality of vehicle calibration sets; and
calculating one or more numerical relationships for each corresponding vehicle parameter of each vehicle calibration set against a corresponding vehicle parameter of all other vehicle calibration sets.

5. The method of claim 4, wherein calculating the anomaly score includes:
calculating a provisional anomaly score for each corresponding vehicle parameter of the plurality of vehicle calibration sets based on a cost function, a weighted value of the gradient, and weighted values of the one or more numerical relationships;
setting the vehicle calibration set having the corresponding vehicle parameter with a lowest provisional anomaly score as a reference vehicle calibration set; and
calculating the anomaly score by adjusting the provisional anomaly score for each corresponding vehicle parameter based on the reference vehicle calibration set.

6. The method of claim 4, wherein the one or more numerical relationships includes a Euclidean distance and a linear regression.

7. The method of claim 1, wherein:
the plurality of vehicle calibration sets includes a master vehicle calibration set and one or more child vehicle calibration sets; and
calculating the anomaly score includes:
calculating a distance for each corresponding vehicle parameter of each child vehicle calibration set against a corresponding vehicle parameter of the master vehicle calibration set; and
calculating the anomaly score based on the distance.

8. The method of claim 7, wherein calculating the anomaly score includes:
calculating a normalized value of the distance; and
setting the anomaly score to equal the normalized value.

9. The method of claim 1, wherein calculating the anomaly score includes:
calculating a mean for each corresponding vehicle parameter of the plurality of vehicle calibration sets;
calculating a distance for each corresponding vehicle parameter of each vehicle calibration set against the calculated mean for that vehicle parameter; and
calculating the anomaly score based on the distance.

10. The method of claim 9, wherein calculating the anomaly score includes:
calculating a normalized value of the distance; and
setting the anomaly score to equal the normalized value.

11. The method of claim 1, further comprising detecting whether the plurality of vehicle calibration sets are in a scalar format, wherein calculating the anomaly score includes, in response to the plurality of vehicle calibration sets being in the scalar format, calculating a distance for each corresponding vehicle parameter of each set of vehicle calibrations against a reference value and calculating the anomaly score based on the distance.

12. The method of claim 1, further comprising detecting whether the plurality of vehicle calibration sets are in a vector format or a map format, wherein calculating the anomaly score specific to each set of vehicle calibrations includes calculating the anomaly score based on a cost function in response to the plurality of vehicle calibration sets being in the vector format or the map format.

13. The method of claim 1, further comprising transmitting a visualization including the anomaly score associated with the detected anomaly to a display module.

14. The method of claim 13, wherein the visualization includes at least one graph charting the anomaly score.

15. The method of claim 13, further comprising receiving user input in response to the transmitted visualization, wherein modifying the vehicle parameter of the vehicle calibration set includes modifying the vehicle parameter of the vehicle calibration set in response to the received user input.

16. The method of claim 1, further comprising:
calculating one or more statistical relationships of corresponding vehicle parameters of the plurality of vehicle calibration sets; and
transmitting a visualization including at least one table charting the one or more statistical relationships to a display module.

17. The method of claim 1, wherein:
the method further comprises receiving a defined autocorrect threshold; and
modifying the vehicle parameter of the vehicle calibration includes autocorrecting the vehicle parameter of the vehicle calibration to a reference calibration in response to the detected anomaly being greater than the defined autocorrect threshold.

18. The method of claim 1, wherein transmitting the vehicle calibration set including the modified vehicle parameter to the vehicle control module includes transmitting the vehicle calibration set to the vehicle control module associated with the vehicle via an over-the-air (OTA) update.

19. A method for detecting anomalies in vehicle calibrations sets, the method comprising:
receiving a plurality of vehicle calibration sets, each vehicle calibration set including corresponding vehicle parameters divided into two or more sections;
calculating, for each section of each vehicle calibration set, an anomaly score;
detecting an anomaly associated with at least one section of a vehicle calibration set of the plurality of vehicle calibration sets based on the anomaly score for the section and a defined threshold;
in response to detecting the anomaly, modifying a vehicle parameter in the section of the vehicle calibration set; and
transmitting the vehicle calibration set including the modified vehicle parameter to a vehicle control module associated with a vehicle for controlling at least one component of the vehicle.

20. A system for detecting anomalies in vehicle calibrations sets, the system comprising:
a vehicle control module associated with a vehicle for controlling at least one component of the vehicle; and
a control module in communication with the vehicle control module, the control module configured to:
receive a plurality of vehicle calibration sets, each vehicle calibration set including corresponding vehicle parameters;
calculate, for each vehicle parameter of each vehicle calibration set, an anomaly score;
detect an anomaly associated with at least one vehicle parameter of a vehicle calibration set of the plurality of vehicle calibration sets based on the anomaly score for the vehicle parameter and a defined threshold;
in response to detecting the anomaly, modify the vehicle parameter of the vehicle calibration set; and
transmit the vehicle calibration set including the modified vehicle parameter to a vehicle control module associated with a vehicle for controlling at least one component of the vehicle.
